(19) United States
(12) Patent Application Publication
(10) Pub. No.: US 2006/0012392 A1
(43) Pub. Date: Jan. 19, 2006

(54) System and method for front-end bypass testing in an electronic circuit

(76) Inventors: Michael A. Rencher, Corvallis, OR (US); James R. Emmert, Corvallis, OR (US)

Correspondence Address: AGILENT TECHNOLOGIES, INC.;Legal Department, DL 429, Intellectual Property Administration, P.O. Box 7599, Loveland, CO, 80537-0599, US

(21) Appl. No.: 10/892,058

(22) Filed: Jul. 15, 2004

(51) Int. Cl. H03K 19/00

(52) U.S. Cl. 326/16

(57) ABSTRACT

A system and method for front-end bypass testing in an electronic circuit. According to one embodiment, the integrated circuit that includes a memory block having at least one input and at least one output that wherein a critical path in the integrated circuit exists through the memory block. At least one input is associated with a block of input logic and at least one output is associated with a block of output logic. The integrated circuit also includes a test circuit coupled to the memory block and operable to verify the block of input logic and the block of output logic while at the same time not impacting the critical path of the integrated circuit.

### BACKGROUND OF THE INVENTION

Application Specific Integrated Circuits (ASICS) in conjunction with Electronic Circuit Boards (ECBS) are prevalent in today's electronics as they are becoming more functional and easier and cheaper to manufacture. As a result, the need to test an ASIC or ECB after manufacture for the purposes of quality assurance has arisen. Various tests involving forced logical values at electronic circuit inputs can be performed on the ASIC or ECB to verify that the design has been implemented correctly. Typically, because the design is known beforehand, a forced logical value at each input point will yield an expected logical value at each output which can be monitored to verify the expected results with respect to every possible combination of input values.

In the past, a technician would typically connect each input of an electronic circuit to be tested to a logic-value generator and each output to a logic-value reader. Then, the technician could force the inputs to a specific pattern of logical values (e.g., ones and zeroes) to determine if the output points behaved as expected. This, of course, becomes very time and labor intensive for larger ASICs and ECBs. As such, tools, such as an Automatic Test Pattern Generator (ATPG), were developed to alleviate the time and labor involved. With an ATPG, the technician only needs to configure the ATPG once with the correct parameters for the electronic circuit to be tested and then place it in the ATPG. The ATPG is then able to test the electronic circuit using every possible combination of inputs to verify expected outputs. This test, which is sometimes called a scan vector test or simply, scan vectors, may be easily repeated for other similar electronic circuits.

Scan vectors work very well for electronic circuits that only have logical circuitry. However, some electronic circuits also have memory blocks that are not as predictable as logical circuits. More specifically, memory blocks, such as Random Access Memory (RAM), are very difficult to test when part of an electronic circuit because predicting the value at an output of a RAM block based on the input requires knowledge of the values currently stored in the cells of the RAM block. Thus, the technician would again need to individually test each and every input and output without the benefit of automation using an ATPG.

FIG. 1 is a schematic drawing of a conventional electronic circuit having a RAM block 100 that includes associated input logic 110 and output logic 120. The associated input logic 110 and output logic 120 is typically included in a package operable to interface with a larger electronic system (not shown). The input logic 110 and the output logic 120 are typically designed to provide the appropriate logical interface with the RAM block 100 since the RAM block 100 is typically a standard, “off-the-shelf” item. As such, for the larger electronic system to interface with the RAM block 100, input logic 110 and output logic 120 are designed to provide signal paths to and from the RAM block 100. Furthermore, in FIG. 1 and throughout this disclosure, memory blocks, such as RAM block 100 include many inputs and many outputs, but only one input path 101 and one output path 102 is shown for clarity.

As discussed above, predicting the logic value at the output 102 of the RAM block 100 based on the logic value at the input 101 is not easily accomplished in a testing environment. This also makes it difficult to observe the inputs 101 of the RAM block 100. In FIG. 1, two test flip-flops, a launch flip-flop 111 and a capture flip-flop 121, are used to interface the input logic 110 and the output logic 120, respectively. In a typical testing situation, known logic values forced at the launch flip-flop 111 will necessarily cause predictable logic values at the capture flip-flop 121. However, because the RAM block 100 is not predictable, there is no way to verify the design of the input logic 110 and output logic 120 because the logic value at the capture flip-flop 121 cannot be predicted based upon the logic value forced at the launch flip-flop 111. Thus, in an electronic circuit such as in FIG. 1, conventional means for verifying the logical circuitry comprising the input logic 110 and the output logic 120 cannot be used. As a result, the input logic 110 and the output logic 120 remain untested and unverified.

FIG. 2 is a schematic diagram of a conventional electronic circuit having a solution of the past that implements a bypass circuit in conjunction with a RAM block 200. In this solution, a bypass multiplexor 205 is used to select between the actual output signal at the output 202 of the RAM block 200 or a bypass signal on a bypass signal line 230 connected directly to the input of the RAM block 200. A scan mode bit 206 sets the bypass multiplexor 205 to select one signal over the other. By setting the scan mode bit 206 at the multiplexor 205 to a high logic value, a signal on the bypass signal line 230 is allowed to pass through the bypass multiplexor 205 and a signal from the output 202 of the RAM block 200 is ignored. In this manner, a technician can predict exactly how the entire logical path between the input logic 210 and the output logic 220 will behave. Thus, a conventional scan vector test used in an ATPG will be able to verify the input logic 210 and output logic 220 when the scan mode bit 206 is set to a high logic value.

On the other hand, when not in scan mode (i.e., scan mode bit 206 is set to a low logic value), any signal that reaches the input 201 of the RAM block 200 propagates normally through the RAM block 200 and a logic value is generated at the output 202 of the RAM block 200 accordingly. The output logic value passes through the bypass multiplexor 205 to the output logic 220 because the Scan Mode bit 206 is set to a low logic value at the bypass multiplexor 205. At the same time, any signal that propagates on the bypass signal line 230 will terminate at the bypass multiplexor 205 because the scan mode bit 206 is set to a low logic value. As a result, the entire electronic circuit behaves as though no bypass circuit were present.

Some problems, however, present themselves with this solution. One such problem involves timing exceptions that arise when the logical path is tested using a bypass circuit. Typically, during a test using an ATPG to generate scan vectors, it is desirable to do so “at-speed.” That is, it is more beneficial to test the electronic circuit at the speed at which it normally operates which implies proper timing with respect to the number of clock cycles and the period of those clock cycles. As such, an electronic circuit having a RAM block 200 between input logic 210 and output logic 220 will take two clock cycles for an operation to complete. During a first clock cycle, a logic value is input to the RAM block 200 and during a second clock cycle, the RAM block 200 generates a logical output value. As a result, the typical operation of the circuit in FIG. 2 requires two clock cycles for signals to propagate from the launch flip-flop 211 to the capture flip-flop 221.

In scan mode (i.e., scan mode bit 206 is set to a high logic value), however, the logic value propagates from the input logic 210 through the bypass signal line 230 to the output logic 220 on a single clock cycle. Thus, a timing problem arises when testing the logical circuits 210 and 220. The timing problem is caused by the fact that the data must propagate through both input logic 210 and output logic 220 in one clock cycle during scan model, while in non-scan mode (scan mode bit 206 is set to a low logic value) the data has almost 2 clock cycles to propagate through the same logic (input logic 210 and output logic 220). Thus, the test results do not accurately reflect the actual performance of the electronic circuit. This problem makes it difficult or impossible to test this particular path “at-speed” with respect to the larger electronic system in which the electronic circuit is part (i.e., the ASIC).

FIG. 3 is a schematic diagram of a conventional electronic circuit that includes a bypass flip-flop 340, between the input logic 310 and the multiplexor 305, which solves the timing issues discussed above with respect to FIG. 2. In this solution, like the one discussed above in FIG. 2, a bypass multiplexor 305 is used to select between the actual output signal at the output 302 of the RAM block 300 or a bypass signal on a bypass signal line 330 connected directly to the input of the RAM block 300. A scan mode bit 306 sets the bypass multiplexor 305 to select one signal over the other. Again, by setting the scan mode bit 306 to a high logic value, a signal from the bypass flip flop 340 is allowed to pass through the bypass multiplexor 305 and any signal from the output 302 of the RAM block 300 is rejected. In this manner, a technician can predict exactly how the entire logical path between the input logic 310 and the output logic 320 will behave. Thus, a conventional scan vector test using an ATPG will be able to verify the input and output logic 310 and 320 when the scan mode bit 306 is set to a high logic value.

The bypass signal line flip-flop 340 provides a capture device that passes the value of the signal on the input 301 of the RAM block 300 to the multiplexor 305 on a subsequent clock signal. As a result, in scan mode (i.e., when the scan mode bit 306 is set to a high logic value), the signal propagating though the bypass signal line 330 and the bypass signal line flip-flop 340 behave more like the RAM block 300 because two clock cycles are used to fully propagate signals from the launch flip-flop 311 to the capture flip-flop 321.

This solution allows the electronic circuit to be tested “at-speed” with respect to the rest of the electronic system (i.e., the ASIC); however, other problems are still present. In some electronic circuits, the critical path is very important, and any additional circuitry that is inserted into the electronic circuit may affect the critical path, i.e., add time to the propagation of signals through the electronic circuit. As such, the bypass multiplexor 205 and 305 of either FIG. 2 or FIG. 3 may add to the critical path. Typically, an added multiplexor may cause a timing addition of 100 picoseconds or more which is unacceptable for high-performance electronic circuits.

FIG. 4 is a schematic diagram of yet another conventional circuit for testing logic in an electronic circuit that includes a RAM block 400 or other similar memory block. Instead of a bypass multiplexor of the previous solutions in FIG. 2 and FIG. 3, the electronic circuit of FIG. 4 utilizes registered tri-state circuitry. Some RAM blocks 400 or other memory blocks are available with outputs 402 that are tri-state capable.

Devices that are tri-state enabled use an enable bit, such as scan mode bit 406, to set each respective output 402 to be enabled. Thus, when tri-state outputs 402 are enabled (i.e., the scan mode bit 406 is set to a low logic value), the outputs 402 of the RAM block 400 function normally. During a scan test, however, the scan mode bit 406 may be set to a high logic value and the outputs 402 of the RAM block 400 are then disabled. At the same time, a bypass signal line 430 which is connected directly to the inputs 401 of the RAM block 400 are coupled to a bypass tri-state driver 405, such that the signal on the bypass signal line 430 is allowed to pass when the scan mode bit 406 is set to a high logic value. In this manner, a technician can again predict exactly how the entire logical path between the input logic 410 and the output logic 420 will behave because the input signal bypasses the RAM block 400 through the bypass signal line 430 during a scan test. Therefore, a conventional scan vector test in an ATPG will be able to verify the input logic 410 and output logic 420.

The conventional solution of FIG. 4 also suffers from similar problems that the conventional solutions of FIG. 2 and FIG. 3. For example, the solution still requires additional circuitry for the bypass signal line 430 in addition to requiring that the RAM block 400 have tri-state outputs. This requirement then leads to more complicated interfaces with the ATPG which may not be configured to handle tri-state circuitry. Furthermore, devices having tri-state driver outputs maybe more expensive than devices that have normal outputs in terms of size and performance. Additionally, as was the case before, the critical path timing is still impacted because tri-state driver 405 and the bypass flip-flop 440 add loading which will lead to additional propagation time.

### SUMMARY OF THE INVENTION

An embodiment of the invention is directed to an integrated circuit that includes a memory block having at least one input and at least one output that wherein a critical path in the integrated circuit exists through the memory block. At least one input is associated with a block of input logic and at least one output is associated with a block of output logic. The integrated circuit further includes a test circuit coupled to the memory block and operable to verify the block of input logic and the block of output logic while at the same time not impacting the critical path of the integrated circuit.

According to one embodiment, the test circuit includes a launch flip-flop operable to force a logic value on the input through the block of input logic, a capture flip-flop operable to read a logic value received from the output through the block of output logic, and a bypass circuit coupled to the launch flip-flop and the memory block which is operable to receive a logic value from the launch flip-flop, select a test mode input in the memory block different from the other input to the memory block, and pass the logic value to the output.

Such a test circuit is able to be used to verify the logic blocks of an integrated circuit without impacting the critical path of various functional signals in an integrated circuit. As a result, time-critical functions that require time-critical integrated circuits can still use a mass-produced integrated circuit having test circuitry therein for use with a typical ATPG that performs a standard scan vector test.

### BRIEF DESCRIPTION OF THE DRAWINGS

The foregoing aspects and many of the attendant advantages of this invention will become more readily appreciated as the same become better understood by reference to the following detailed description, when taken in conjunction with the accompanying drawings, wherein:

FIG. 1 is a schematic drawing of a conventional electronic circuit having a RAM block that includes associated input logic and output logic;

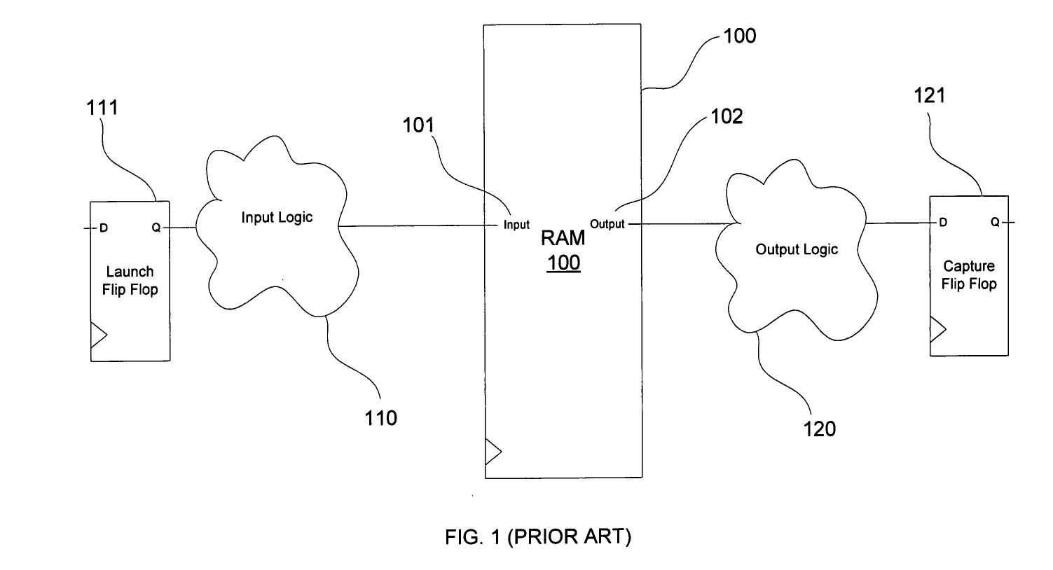

FIG. 2 is a schematic diagram of a conventional electronic circuit having a solution of the past that implements a multiplexor bypass circuit in conjunction with a RAM block;

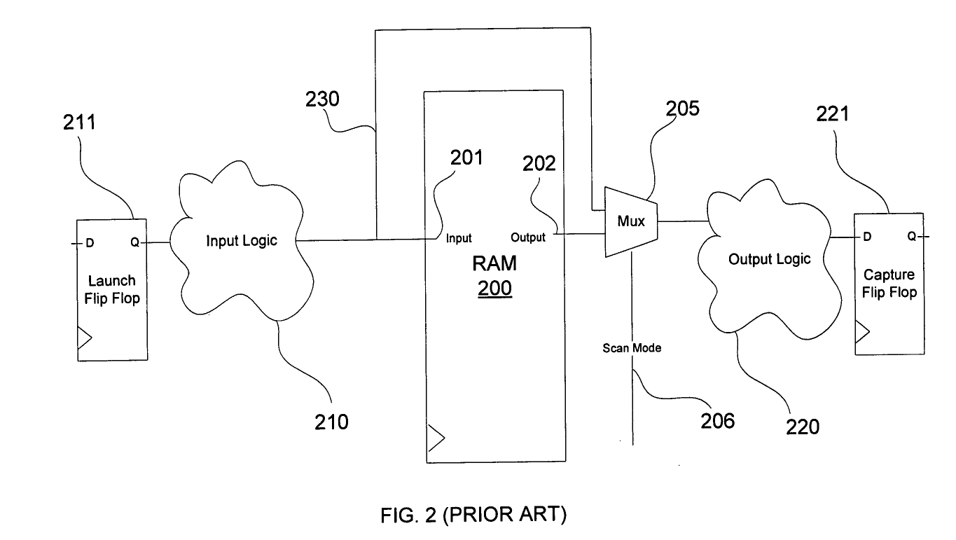

FIG. 3 is a schematic diagram of a conventional electronic circuit that includes a bypass flip-flop that solves the complex timing issues associated with the conventional electronic circuit of FIG. 2;

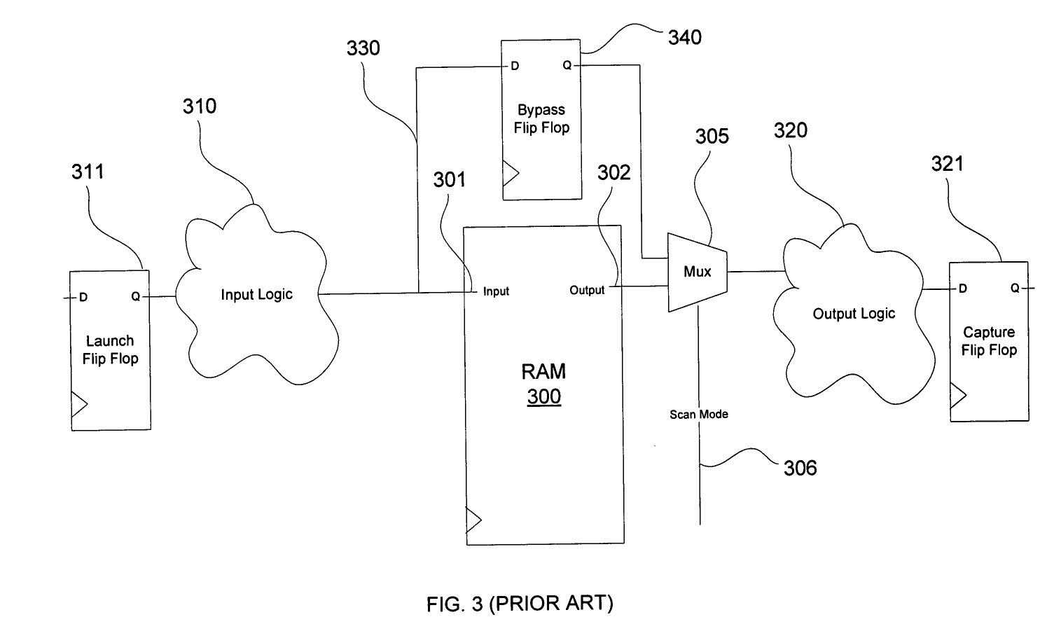

FIG. 4 is a schematic diagram of yet another conventional circuit for testing logic in a circuit that includes RAM blocks or other similar memory devices;

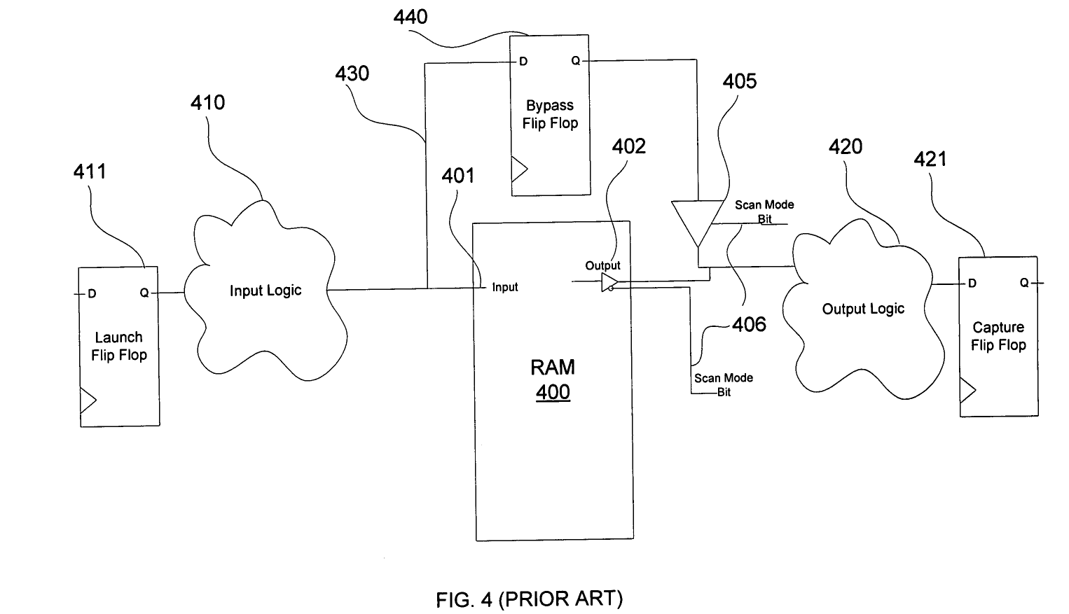

FIG. 5 is a schematic diagram of an electronic circuit having a front-end bypass test circuit for testing logic according to an embodiment of the invention; and

FIG. 6 is a block diagram of a typical ATPG that may be used in conjunction with the electronic circuit of FIG. 5 according to an embodiment of the invention.

### DETAILED DESCRIPTION

The following discussion is presented to enable a person skilled in the art to make and use the invention. The general principles described herein may be applied to embodiments and applications other than those detailed above without departing from the spirit and scope of the present invention. The present invention is not intended to be limited to the embodiments shown, but is to be accorded the widest scope consistent with the principles and features disclosed or suggested herein.

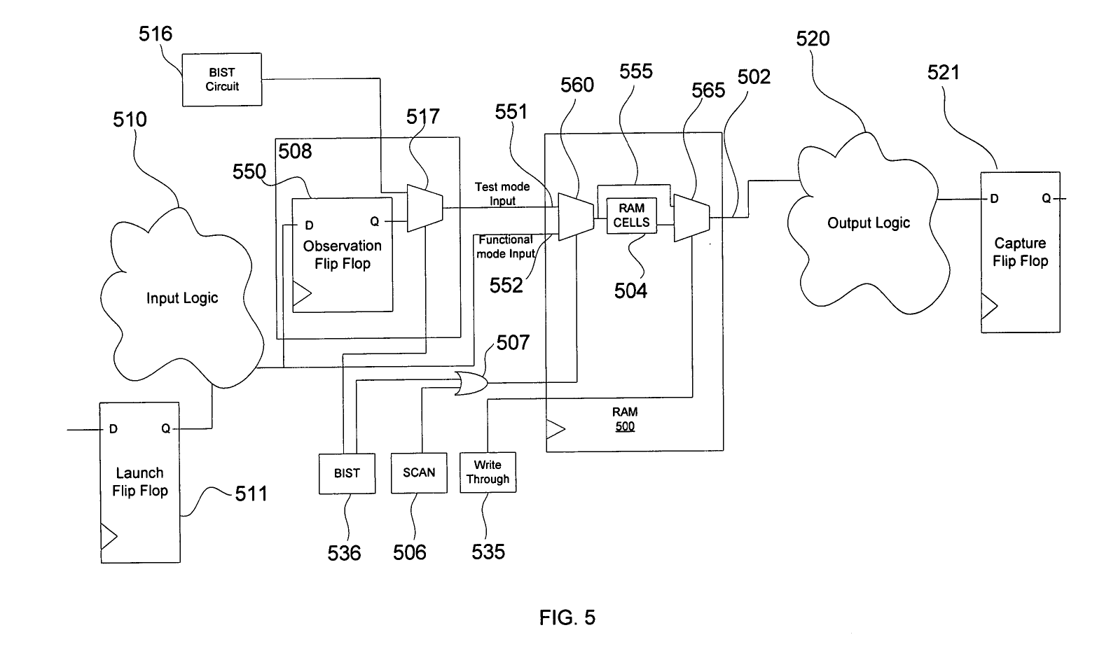

FIG. 5 is a schematic diagram of an electronic circuit having a front-end bypass test circuit for testing logic according to an embodiment of the invention. The electronic circuit includes typical elements associated with an ATPG such as launch flip-flop 511 and capture flip-flop 521. The electronic circuit to be tested resides between the launch flip-flop 511 and the capture flip-flop 521 and, in this embodiment, the electronic circuit to be tested includes input logic 510 and output logic 520 associated with a memory block, such as the RAM block 500. The electronic circuit also includes front-end bypass circuitry 508. These elements and their relationships between each other are detailed in the following paragraphs.

As was discussed previously in the background section, it is extremely difficult to predict the logical outcome of values passed through a memory block in an electronic circuit using a scan vector test in an ATPG tester. As such, a reliable and predictable way of passing logical values either through or around the memory block is needed such that known values loaded at the launch flip-flop 511 will yield expected logical values at the capture flip-flop 521.

One such way utilizes an off-the-shelf type of memory block that includes a write-through capability and a Built-In Self-Test mode (BIST mode) inputs. A memory block that has write-through capability, such as RAM block 500, monitors a specific write-through input 535 to determine the operation of its inputs and outputs. In one embodiment, if the write-through input 535 is set to a low logic value, the outputs of the RAM block 500 typically operate normally according to the functions of the memory blocks. On the other hand, if the write-through input 535 is set to a high logic value, the outputs of the RAM block 500 typically reflect the logic value of respective corresponding inputs. That is, any logic value received on an input will be written directly through to a corresponding output. Although discussed in more detail below with respect to the operation of the embodiment of FIG. 5, memory blocks having write-through capability are well-known in the industry and will not be discussed in further detail herein.

The RAM block 500 also includes a BIST mode such that another input is able to set the RAM block 500 to a BIST mode (e.g., BIST input 536 set to a high logical value) or a functional mode (e.g., BIST input 536 set to a low logical value). When in BIST mode, a memory block will typically receive inputs through dedicated test inputs (e.g., test mode input 551) and when in functional mode, a memory block will receive inputs through dedicated functional mode inputs (e.g., functional mode input 552). As a result, when in BIST mode, logical values on the functional input 552 will be ignored, and, when in functional mode, logical values on the test mode input 551 will be ignored. Again, this aspect of the RAM block 500 is discussed in more detail below with respect to the operation of the embodiment of FIG. 5; however, memory blocks having BIST capability are also well-known in the industry and will not be discussed in further detail herein.

As can be seen in FIG. 5, the electronic circuit monitors inputs that include write-through input 535, BIST input 536, and scan mode input 506. Various combinations of logical values on these inputs control some aspects of the operation of the entire electronic circuit. The schematic layout and connections of these inputs are discussed below and then a discussion of the operation of the electronic circuit in the various combinations of input values is presented.

The write-though mode input 535 controls the operation of the output multiplexor 565 (only one is shown for clarity, but several may all be linked to the same write-through mode input 535). In one embodiment, when the write-through input 535 is set to a low logic value, the output multiplexor 565 recognizes the logical values received from the RAM cells 504 according to normal operation of the RAM block 500 and passes these logic values to the output 502 of the RAM block 500 (again, only one shown for clarity), while at the same time ignoring any logic value on the write-through bypass line 555. Likewise, when the write-through input 535 is set to a high logic value, the output multiplexor 565 recognizes the logical values received on the write-through bypass line 555 and also passes these logic values to each respective RAM block output 502, while at the same time ignoring any logic value from the RAM cells 504.

Similarly, the BIST input 536 controls the operation of the input multiplexor 560 (only one is shown for clarity, but several may all be linked to the same BIST mode input 536). This input multiplexor can reside inside or outside of the RAM block. In one embodiment, when the BIST input 536 is set to a high logic value, the input multiplexor 560 recognizes the logical values received on the test mode input 551 and passes these logic values accordingly, while at the same time ignoring any logic value on the functional mode input 552. Likewise, when the BIST input 536 is set to a low logic value, the input multiplexor 560 recognizes the logical values received on the functional mode input 552 and also passes these logic values accordingly while at the same time ignoring any logic value on the test mode input 551.

Both the write-through mode and BIST mode are discussed in greater detail below with respect to the operation of this embodiment of the electronic circuit of FIG. 5.

As was briefly mentioned above, the embodiment of FIG. 5 includes front-end bypass circuitry 508 for handling scan tests when in an ATPG environment. The front-end bypass circuitry 508 includes an observation flip-flop 550 and a front-end multiplexor 517. The input of the observation flip-flop 550 is coupled to the functional input 552 of the RAM block 500. The electronic circuit of FIG. 5 may include bypass circuitry 508 for each input to the RAM block 500, but only one is shown here for clarity. The output of the observation flip-flop 550 is coupled to one of two selectable inputs on the front-end multiplexor 517. The other input of the front-end multiplexor 517 is coupled to a signal line from a BIST circuit 516 (not shown in detail).

The input which the front-end multiplexor 517 selects is determined by the logic value of the BIST input 536. In one embodiment, when the BIST input 536 is set to a high logic value, the front-end multiplexor 517 recognizes the logical values received from the BIST circuit 516 and passes these logic values accordingly while at the same time ignoring any logic value from the observation flip-flop 550. Likewise, when the BIST input 536 is set to a low logic value, the front-end multiplexor 517 recognizes the logical values received from the observation flip-flop 550 and passes these logic values accordingly while at the same time ignoring any logic value from the BIST circuit 516.

In a similar manner to the BIST input 536, the scan mode input 506 also controls the operation of the input multiplexor 560 (only one is shown for clarity, but several may all be linked to the same scan mode input 506). In one embodiment, when the scan mode input 506 is set to a high logic value, the input multiplexor 560 recognizes the logical values received on the test mode input 551 and passes these logic values accordingly. Likewise, when the scan mode input 506 is set to a low logic value, each input multiplexor 560 recognizes the logical values received on the functional mode input 552 and also passes these logic values accordingly. Since the input multiplexor 560 is coupled to two different inputs (scan mode input 506 and BIST input 536), if either one is set to a high logic value, then the input multiplexor 560 selects the test mode input 551 for passing signals and rejects logic values on the functional mode input 552. This may be accomplished by using OR gate 507 such that the signal line controlling the input multiplexor 560 is a high logic value if either the scan mode input 506 or BIST input 536 or both are at a high logic value.

With these three inputs (scan mode input 506, BIST input 536, and write-through input 535) controlling some aspects of the operations of the electronic circuit, eight possible control states exist with respect to these three binary input values. While a technician has the option of setting up to eight control states using the three binary inputs values, the primary control states for the purposes of the present invention include a functional mode state, a scan mode state, and a BIST mode state. Although other input combinations exist (and consequently, other possible control states, such as write-though mode), only the afore-mentioned control states will be discussed herein as the other combinations may be duplicative and/or unused.

In a first control state, the electronic circuit may be set for functional mode. In this control state, each of the inputs (write-through input 535, scan mode input 506, and BIST input 536) is set to a low logic value. As such, logic signals that are initiated at the launch flip-flop 511 propagate through the input logic 510 to the functional mode input 552. At the input multiplexor 560, the logic value at the functional mode input 552 is recognized while any logic value at the test mode input 551 is ignored because neither the scan mode input 506 nor the BIST input 536 is set to a high logic value. Thus, only the logic value on the functional mode input 552 is allowed to pass. Furthermore, even though logic values are, in fact, passed through the observation flip-flop 550 and the front-end multiplexor 517, any resultant logic value on the test mode input 551 is ignored because the input multiplexor 560 is set to only pass logic values on the functional mode input 552. In essence, when in functional mode operation, the electronic circuit is unconcerned with any signals propagating through the front-end circuitry 508.

Once logic values are passed to the RAM block 500 at the input multiplexor 560, the RAM block 500 behaves normally. That is, input values are passed to RAM cells 504 according to the parameters of operation of the RAM block 500 itself. Additionally, all logic values at the input multiplexor 560 are passed along the write-through bypass line 555 to the output multiplexor 565. The output multiplexor 565 is set to only recognize logic values from the RAM cells 504, however, as the write-through mode input 535 is set to a low logic value when in functional mode operation. As a result, even though logic values are passed to the output multiplexor 565 on the write-through bypass line 555, the output multiplexor 565 ignores these logic values because the write through input 535 is set to a low logic value. The recognized logic values from the RAM cells 504 are passed to the output 502 of the RAM block 500, then to the output logic 520, and eventually to the capture flip-flop 521.

The front-end bypass circuit 508 is not used in functional mode since its main purpose is control and observation of the RAM block inputs 551 during scan mode. Furthermore, the timing of signals propagating through the electronic circuit will be approximately two clock cycles. During a first clock cycle, a logic value propagates to the input of the RAM block 500 through the input logic 510. Likewise, during a second clock cycle, the logic value propagates from the output of the RAM block 500 through the output logic 520. The additional time that it takes a signal to pass through the multiplexors 560 and 565 inside the RAM block 500 have a negligible timing impact with respect to the two clock cycles during functional mode operation despite the fact that they are designed into the RAM block 500 and are not removable. Thus, it is desirable that any testing of the electronic circuit is also accomplished in the same time frame (i.e., two clock cycles).

When a technician needs to test the input logic 510 and output logic 520 using an ATPG, the technician may set the scan mode control state wherein the scan mode input 506 is set to a high logic value. At the same time, the write-through input 535 is also set to a high logic value to take advantage of the write-through capability of the RAM block 500. The BIST input 536 remains at a low logic value during an ATPG test.

In this control state (scan mode), logic signals that are initiated at the launch flip-flop 511 propagate normally through the input logic 510 to the functional mode input 552. At the input multiplexor 560, any logic value at the functional mode input 552, however, is ignored, while, at the same time, any logic value at the test mode input is recognized because the scan mode input 506 is set to a high logic value which controls the input multiplexor 560. Thus, only the logic value on the test mode input 551 is allowed to pass. Any resultant logic value on the test mode input 551 is recognized and passed because the input multiplexor 560 is set to only pass logic values on the test mode input 551. In essence, when in scan mode operation, the electronic circuit is unconcerned with any signals propagating to the functional mode input 552 at the RAM block 500.

Furthermore, logic values on the functional mode input 552 are also the same as logic values at the input to the observation flip-flop 550, and are passed through the observation flip-flop 550 and the front-end multiplexor 517 accordingly. The front-end bypass multiplexor 517, in scan mode, is set to recognize and pass logic values from the output of the observation flip-flop 550 while ignoring any logic values from the BIST circuit 516. This is because the BIST input 536 is still set to a low logic value.

Once logic values are passed to the RAM block 500 at the input multiplexor 560, the RAM block 500 again behaves normally. That is, input values are passed to RAM cells 504 according to the parameters of the RAM block 500 itself. Additionally, all logic values at the input multiplexor 560 are passed along the write-through bypass line 555 to the output multiplexor 565. However, in scan mode, the output multiplexor 565 is set to only recognize logic values from the write-through bypass line 555 and to ignore any logic values from the RAM cells 504. This is because the write-through mode input 535 is set to a high logic value when in scan mode operation. As a result, even though logic values are passed to the output multiplexor 565 from the RAM cells 504, the output multiplexor 565 ignores these logic values because the write through input 535 is set to a high logic value. The recognized logic values from the write-through bypass line 555 are passed to the output 502 of the RAM block 500, then to the output logic 520, and eventually to the capture flip-flop 521.

In scan mode, the launch flip-flop 511 and the capture flip-flop 521 will, in fact, be part of the overall logical circuitry in the electronic circuit as these flip-flops are a typical feature of an ATPG environment that facilitates the testing procedure. Furthermore, much like the timing of signals in functional mode, the timing of signals propagating through the electronic circuit in scan mode will also be approximately two clock cycles. During a first clock cycle, a logic value propagates to the input of the observation flip-flop 550 through the input logic 510. Likewise, during a second clock cycle, the logic value propagates from the output observation flip-flop 550 through the RAM block 500 and the output logic 520. Again, the additional time that it takes a signal to pass through the multiplexors 560 and 565 inside the RAM block 500 as well as the bypass multiplexor 517 is negligible with respect to the two clock cycles during scan mode operation. Therefore, any testing of the logic is accomplished in the same time frame (i.e., two clock cycles) as the timing of the functional mode. That is, the scan test may be run at-speed.

Furthermore, the bypass circuitry 508 is not within the critical path of the electronic circuit. Thus, the critical path of the electronic circuit will remain as fast as possible while at the same time still having test circuitry (bypass circuitry 508) for testing the circuit at-speed.

A third control state that is available in this embodiment of the invention is a BIST mode. In this control state, logic signals that are initiated at the launch flip-flop 511 (or any other circuit that may be coupled to the input logic 510) propagate normally through the input logic 510 to the functional mode input 552. As was the case with scan mode, at the input multiplexor 560, the logic value at the functional mode input 552 is ignored. Any logic value at the test mode input 551 is recognized because the BIST input 536 is set to a high logic value. Thus, only logic values on the test mode input 551 are allowed to pass and any resultant logic values on the test mode input 551 are recognized and passed because the input multiplexor 560 is set to only pass logic values on the test mode input 551. In essence, when in BIST mode operation, the electronic circuit is unconcerned with any signals propagating to the functional mode input 552 at the RAM block 500.

The front-end bypass multiplexor 517, in the BIST mode, is set to recognize and pass logic values from the BIST circuit 516 while ignoring any logic values from the output of the observation flip-flop 550. This is because the BIST mode input 536 is set to a high logic value causing the bypass multiplexor 517 to only recognize and pass signals from the BIST circuit 516.

Once logic values are passed to the RAM block 500 at the input multiplexor 560, the RAM block 500 behaves according to the parameters of the BIST testing procedures. The BIST parameters are not described in further detail as they are not within the scope of the present invention. Thus, signals may be passed to the output 502 of the RAM block 500, then to the output logic 520 and eventually to the capture flip-flop 521 according to known BIST test procedures.

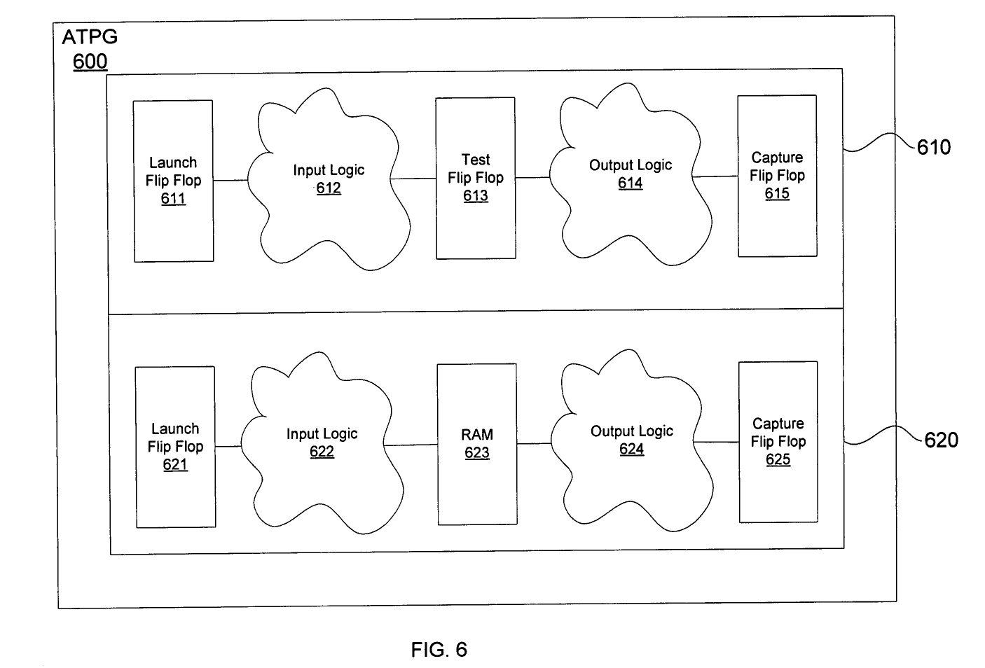

FIG. 6 is a block diagram of a typical ATPG 600 that may be used in conjunction with the electronic circuit of FIG. 5 according to an embodiment of the invention. The ATPG 600 includes two test paths that may be used to compare a first electronic circuit against a standard test circuit or a second electronic circuit. As shown, the first path 610 includes a first launch flip-flop 611, a first input logic 612 a test flip-flop 613, a first output logic 614 and a first capture flip-flop 615. Likewise, the second path 620 also includes a second launch flip-flop 621, a second input logic 622, a second output logic 624, and a second capture flip-flop 625. Additionally, instead of a test flip-flop, the second path 620 includes a device between the input logic 622 and output logic 624, such as RAM block 623. The second input logic 622, the RAM block 623 and the output logic 624 may be similar to the electronic circuit of FIG. 5 and may also include the bypass circuitry 508 of FIG. 5.

As such, a technician may perform a scan vector test using the ATPG 600 of FIG. 6 on both the first path 610 and the second path 620. The results may be analyzed and compared according to known test procedures. Furthermore, each test may be performed at-speed such that testing is accomplished at the same speed in which the electronic circuit in either path would operate normally.

We claim:

1. An integrated circuit, comprising:
a memory block having at least one input and at least one output that includes a critical path, at least one input associated with a block of input logic and the at least one output associated with a block of output logic; and
a test circuit coupled to the memory block and operable to verify the block of input logic and the block of output logic wherein the test circuit does not affect the critical path.

2. The integrated circuit of claim 1 wherein the test circuit comprises:
a launch flip-flop operable to force a logic value on at least one input through the block of input logic;
a capture flip-flop operable to read a logic value received from at least one output through the block of output logic; and
a bypass circuit coupled to the launch flip-flop and the memory block and operable to receive a logic value from the launch flip-flop, select a test mode input in the memory block different from the at least one input, and pass the logic value to the test mode input.

3. The integrated circuit of claim 2 wherein the bypass circuit comprises:
an observation flip-flop operable to receive a logic value from the block of input logic; and
a front-end multiplexor coupled to an output of the observation flip-flop and operable to pass a logic value received from the observation flip-flop to the test mode input.

4. The integrated circuit of claim 3 wherein the test mode input comprises an input to the memory block wherein a logic value received on the test mode input is passed to a corresponding output of the memory block.

5. The integrated circuit of claim 4 wherein the logic value received on the test mode input is only passed to the corresponding output when a write-through bit is set in the memory block.

6. The integrated circuit of claim 2 wherein the bypass circuit is only operable to pass the logic value to the test mode input when a scan mode bit associated with the memory block is set.

7. The integrated circuit of claim 1 wherein the memory block comprises a random access memory block.

8. The integrated circuit of claim 1 operable to interface with an automatic test pattern generator and operable to be tested by a scan vector test.

9. In an electronic circuit, a method, comprising
launching a logic value from a launch flip-flop to a memory block through a block of input logic;
reading the logic value at an input to an observation flip-flop wherein the observation flip-flop comprises an output coupled to a test mode input in the memory block;
passing the logic value from the observation flip-flop to the test mode input;
passing the logic value received at the test mode input to a corresponding output; and
reading the logic value at a capture flip-flop through a block of output logic.

10. The method of claim 9 wherein the passing of the logic value from the observation flip-flop to the test mode input further comprises passing the logic value when a scan mode bit associated with the memory block is set.

11. The method of claim 9 wherein the passing of the logic value from the test mode input to the corresponding output further comprises passing the logic value when a write-through bit associated with the memory block is set.

12. The method of claim 9, further comprising receiving the logic value at a functional mode input of the memory block;
passing the logic value to a memory cell in the memory block when a write-through bit is not set; and
passing a second logic value associated with the logic value received at the memory cell to the capture flip-flop through an output of the memory block.

13. The method of claim 12 wherein the logic value passed through the observation flip-flop propagates to the capture flip-flop in an amount of time substantially the same as the amount of time that the logic signal propagates through the memory cell in the memory block to the capture flip-flop.

14. An electronic circuit, comprising:
a launch flip-flop having an input and an output and operable to generate at least one logic value from a signal received at the input of the launch flip-flop;
an input logic block having an input and an output, the input of the input logic block coupled to the output of the launch flip-flop;
a memory block having a test input, a functional input, and an output, the functional input of the memory bock coupled to the output of the input logic block;
an output logic block coupled to the memory block having an input and an output, the input of the output logic block coupled to the output of memory block;
a capture flip-flop having an input and an output, the input of the capture flip-flop coupled to the output of output logic block; and
a test block having an input and an output, the input of the test block coupled to the output of the input logic block and the output of the test block coupled to the test input of the memory block.

15. The electronic circuit of claim 14 wherein the capture flip-flop and the launch flip-flop comprise D-type flip-flops.

16. The electronic circuit of claim 14 wherein the test block comprises:
an observation flip-flop having an input and an output, the input of the observation flip-flop coupled to the input of the test block; and
a test block multiplexor having a first input, a second input, and an output, the first input coupled to the output of the observation flip-flop and the output of the test block multiplexor coupled to the output of the test block.

17. The electronic circuit of claim 16 wherein the second input of the test block multiplexor is coupled to a built-in self test circuit.

18. The electronic circuit of claim 16 wherein the test block multiplexor is operable to recognize the first input while ignoring the second input when a built-in self test mode bit is not set and recognize the second input while ignoring the first input when the built-in self test mode bit is set.

19. The electronic circuit of claim 14 wherein the memory block is operable to recognize the test input while ignoring the functional input when a scan mode bit is set and recognize the second input while ignoring the first input when the scan mode bit is not set.

20. The electronic circuit of claim 14 wherein the memory block comprises memory cells, the memory cells operable to store a logic value received at the memory block when a write through bit is not set and the memory cells being bypassed such that a logic value is passed through the memory block when received when the write-through bit is set.
